(19) United States
(12) Patent Application Publication
(10) Pub. No.: US 2026/0304621 A1
(43) Pub. Date: Oct. 1, 2026

(54) CIRCUIT BOARD, AND SEMICONDUCTOR PACKAGE COMPRISING SAME

(71) Applicant: LG INNOTEK CO., LTD., Seoul (KR)

(72) Inventors: Sung Ho JUNG, Seoul (KR); Byung Youl MOON, Seoul (KR); Hee Yeon CHOI, Seoul (KR)

(73) Assignee: LG INNOTEK CO., LTD., Seoul (KR)

(21) Appl. No.: 19/474,090

(22) PCT Filed: Apr. 15, 2024
(86) PCT No.: PCT/KR2024/005012

§ 371 Date: Oct. 9, 2025

(30) Foreign Application Priority Data
Apr. 13, 2023 (KR) 10-2023-0049045

(51) Int. Cl. H05K 1/11; H05K 1/181; H05K 3/28

(52) U.S. Cl. CPC H05K 1/115; H05K 1/181; H05K 3/28

(57) ABSTRACT

A circuit board according to an embodiment includes a build-up structure; a connection member disposed on the build-up structure; a molding member disposed on the build-up structure and surrounding a side portion of the connection member; and a conductive bonding part penetrating the molding member, wherein the connection member includes a through electrode penetrating at least a portion of the connection member in a vertical direction, a thickness of the conductive bonding part in the vertical direction is greater than a thickness of the through electrode in the vertical direction, and a height of the conductive bonding part is greater than a height of the connection member.

### TECHNICAL FIELD

An embodiment relates to a circuit board and a semiconductor package including the same.

### BACKGROUND ART

As performances of electric/electronic products progresses, technologies for disposing a greater number of packages on a circuit board substrate of a limited size are being proposed and studied.

A typical semiconductor package consists of multiple chips disposed in a single package. Recently, a size of a semiconductor package has increased due to the advancement of product specifications and the adoption of numerous semiconductor devices, such as High Bandwidth Memory (HBM). Accordingly, the semiconductor package includes an interposer to connect a plurality of multiple semiconductor devices.

In addition, semiconductor packages used in products that provide Internet of Things (IoT), autonomous vehicles, and high-performance servers require high performance and reliability due to a trend toward high integration. Here, the high performance may mean that the transmission of a signal is possible at high speed and allowable current of a transmittable signal is high. Also, the high reliability includes a high bonding force between each component constituting the semiconductor package.

Meanwhile, a semiconductor package includes a circuit board and semiconductor devices mounted on the circuit board. The semiconductor devices may have a vertically stacked structure and may be provided in multiples. To this end, the circuit board may include a pad and a conductive bonding part.

A connection member may be disposed on a pad of a circuit board, and a plurality of semiconductor devices may be disposed on the conductive bonding part and connection member of the circuit board.

A semiconductor package includes a molding member disposed between the circuit board and the plurality of semiconductor devices and molding the conductive bonding part.

However, in the semiconductor package according to a prior art, stress due to expansion and/or contraction due to a heat cycle can be continuously transmitted to the molding member, resulting in a problem of deteriorating adhesion between the molding member and the circuit board. As a result, the semiconductor package according to the prior art may have a physical reliability problem in which the molding member is peeled off from the circuit board, and accordingly, there is a problem that the conductive bonding part cannot be stably protected.

In particular, the conductive bonding part can be used as power wiring that supplies power and/or electric power to the plurality of semiconductor devices. At this time, a magnitude of the power and/or electric power provided through the conductive bonding part is also increasing due to the high performance and high reliability of recent semiconductor packages.

According to the prior art, the conductive bonding part may not be stably protected by the molding member, and thus the physical reliability and/or electrical reliability of the conductive bonding part may be deteriorated, and further, a problem may occur in which a plurality of semiconductor devices connected to the conductive bonding part do not operate stably.

### DISCLOSURE

### Technical Problem

An embodiment provides a semiconductor package having a new structure.

In addition, the embodiment provides a semiconductor package capable of improving the adhesion between the circuit board and the molding member.

In addition, the embodiment provides a semiconductor package that can efficiently disperse and/or alleviate stress caused by expansion and/or contraction by a heat cycle.

In addition, the embodiment provides a semiconductor package capable of improving operating characteristics of a semiconductor device.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a build-up structure; a connection member disposed on the build-up structure; a molding member disposed on the build-up structure and surrounding a side portion of the connection member; and a conductive bonding part penetrating the molding member, wherein the connection member includes a through electrode penetrating at least a portion of the connection member in a vertical direction, wherein a thickness of the conductive bonding part in the vertical direction is greater than a thickness of the through electrode in the vertical direction, and wherein a height of the conductive bonding part is greater than a height of the connection member.

In addition, the build-up structure includes a build-up insulating layer stacked in a vertical direction, a pad part disposed on the build-up insulating layer, and a protective layer disposed on the build-up insulating layer and including an opening portion that overlaps the pad part in the vertical direction.

In addition, a side wall of the protective layer forming the opening part has a step, and wherein the molding member contacts at least a portion of the step of the side wall of the protective layer.

In addition, the side wall of the protective layer having the step is provided along a circumferential direction of an outer side surface of the connection member.

In addition, the side wall of the protective layer includes a first part adjacent to a lower surface of the protective layer; and a second part provided on the first part and having a step from the first part.

In addition, at least one of the first part and the second part has a curved surface.

In addition, the opening part of the protective layer has a width in a horizontal direction in the first part greater than that in the horizontal direction in the second part.

In addition, the opening part of the protective layer has a width in a horizontal direction in the first part smaller than that in the horizontal direction in the second part.

In addition, the molding member overlaps at least a portion of the opening part of the protective layer in the vertical direction and contacts each of the first part and the second part of the side wall.

In addition, the molding member does not overlap the opening part of the protective layer in the vertical direction and contacts a portion of the second part of the side wall.

In addition, the conductive bonding part includes a first through part penetrating a protective layer of the build-up structure; and a second through part penetrating the molding member.

In addition, a width of the first through part in the horizontal direction is different from a width of the second through part in the horizontal direction.

In addition, an outer side surface of the protective layer has a step from an outer side surface of the insulating layer.

In addition, the molding member is provided to cover the outer side surface of the protective layer, which has a step from the outer side surface of the insulating layer.

In addition, the outer side surface of the protective layer includes a first portion having a step from the outer side surface of the insulating layer; and a second portion having a step from the outer side surface of the insulating layer and the first portion, and the molding member contacts the first portion and the second portion.

Meanwhile, a semiconductor package according to an embodiment includes a circuit board and a plurality of semiconductor devices disposed on the circuit board, wherein the plurality of semiconductor devices are disposed on the conductive bonding part of the circuit board and the connection member while being spaced apart in the horizontal direction.

In addition, the semiconductor package further includes a first connecting part disposed between the conductive bonding part and the plurality of semiconductor devices; and a second connecting part disposed between the connection member and the plurality of semiconductor devices.

Meanwhile, a circuit board according to an embodiment includes a build-up structure including an insulating layer and a protective layer disposed on the insulating layer, a molding member disposed on the build-up structure; and a conductive bonding part disposed on the insulating layer and penetrating the molding member disposed on the build-up structure, wherein an outer side surface of the protective layer has a step with respect to an outer side surface of the insulating layer, and the molding member is provided to cover the outer side surface of the protective layer.

In addition, the outer side surface of the protective layer includes a first portion having a step with respect to the outer side surface of the insulating layer; and a second portion having a step with respect to the outer side surface of the insulating layer and the first portion, and the molding member is in contact with the first portion and the second portion.

In addition, the circuit board further includes a connection member disposed on the insulating layer, the protective layer includes an opening part overlapping the connection member in a vertical direction, a side wall of the opening part of the protective layer has a step, and the molding member contacts the side wall of the opening part having the step.

Meanwhile, a semiconductor package according to an embodiment includes a plurality of semiconductor devices disposed on the conductive bonding part and the connection member, wherein each of the plurality of semiconductor devices includes a first group of terminals connected to the conductive bonding part and a second group of terminals connected to the connection member, and the first group of terminals includes a power or power supply terminal.

### Advantageous Effects

The semiconductor package of the embodiment includes a circuit board. The circuit board may include an insulating layer, a protective layer, and a molding member. The protective layer may include an opening part overlapping a connection member in a vertical direction. A side wall of the opening part of the protective layer, which overlaps the connection member in a vertical direction, may have a step. Furthermore, a molding member may be disposed on the protective layer and may contact the step of the side wall of the opening part of the protective layer.

Accordingly, the embodiment may increase a contact area between the molding member and the protective layer. Therefore, the embodiment may improve the bonding strength between the molding member and the protective layer, thereby ensuring that the molding member is firmly bonded to the protective layer.

In this case, a conductive bonding part is disposed on the insulating layer and penetrates the protective layer and the molding member. Furthermore, the molding member may mold the conductive bonding part. For example, the molding member may be provided on an outer region of an upper portion of the circuit board, thereby molding the conductive bonding part. At this time, the molding member can contact the step of the side wall of the protective layer, thereby molding the conductive bonding part while being firmly bonded to the protective layer. Therefore, the embodiment can more stably protect the conductive bonding part through the molding member, thereby enabling the semiconductor device connected to the conductive bonding part to operate more stably. For example, the embodiment can enable stable power and/or electric power supply to a semiconductor device using a conductive bonding part, thereby improving the operational reliability of the semiconductor device.

Furthermore, the molding member can be provided to entirely cover the side wall of the opening part of the protective layer. This allows the molding member to mold not only the conductive bonding part but also the side wall of the protective layer. For example, the molding member can mold the conductive bonding part while firmly coupling and fixing the protective layer to the insulating layer. Accordingly, the embodiment can minimize the transfer of stress due to heat cycles caused by expansion and/or contraction of the protective layer to the conductive bonding part, thereby further improving the physical and/or electrical reliability of the semiconductor package.

Furthermore, the side wall of the opening part of the protective layer having a step may have a curved surface. If the side wall of the opening part of the protective layer has a curved surface, the stress caused by expansion and/or contraction due to the heat cycle of the protective layer can be minimized, thereby further improving the physical and/or electrical reliability of the semiconductor package. For example, if the side wall of the opening part is straight line, an edge part where different slopes meet is bent at an angle close to a right angle, as a result, there may be a problem that stress caused by that occur during the operation of the semiconductor devices or heat applied during a process is concentrated in the bent edge part. In contrast, if the side wall of the opening part of the protective layer has a curved surface, the stress can be prevented from concentrating at the edge part and further, the stress can be evenly distributed throughout an entire region of the side wall of the opening part. This can further improve the physical and/or electrical reliability of semiconductor packages, thereby enabling more stable operation of products such as servers.

In addition, the side wall of the opening part of the protective layer may have a step, thereby improving the physical reliability of the protective layer. For example, the protective layer may expand and/or contract due to heat cycles. In this case, the heat cycle resulting from the expansion and/or contraction may cause warping of the protective layer, which may lead to physical reliability issues such as the protective layer being peeled off from the insulating layer. In an embodiment, the side wall of the opening part of the protective layer has a step that includes a first part and a second part. In this case, a surface area of the side wall with the step may be larger than that of the side wall without the step. In this case, when the surface area of the side wall is large, a flow range of the protective layer can be further increased during expansion and/or contraction, thereby minimizing thermal deformation of the protective layer due to expansion and/or contraction. Therefore, the embodiment can resolve the physical reliability issue of the protective layer peeling from the insulating layer, thereby ensuring stable protection of the insulating layer and an electrode part through the protective layer.

Furthermore, an outer side surface of the insulating layer and an outer side surface of the protective layer may have a step. Furthermore, the outer side surface of the insulating layer and the outer side surface of the protective layer having the step may contact the molding member. This allows the contact area between the molding member and the protective layer to be increased. Accordingly, the embodiment may allow the conductive bonding part to be more reliably protected through the molding member, thereby further improving the physical reliability and/or electrical reliability of the semiconductor package.

Furthermore, the embodiment can position the outer side surface of the protective layer further inward than the outer side surface of the insulating layer, thereby preventing warpage of the semiconductor package that may occur due to a difference in coefficients of thermal expansion of the insulating layer and the protective layer.

Furthermore, the molding member may contact the outer side surface of the protective layer having a step from the outer side surface of the insulating layer while contacting the side wall of the opening part of the protective layer having a step. Therefore, the embodiment may more firmly fix the protective layer through the molding member, and may minimize deformation of the protective layer due to expansion and/or contraction due to the heat cycle. Therefore, the embodiment may allow the conductive bonding part to be more stably coupled.

### DESCRIPTION OF DRAWINGS

FIG. 1 is a cross-sectional view illustrating a semiconductor package according to a first embodiment.

FIG. 2 is an enlarged cross-sectional view of a region R1 of FIG. 1.

FIG. 3 is a plan view illustrating a first protective layer and a molding member of FIG. 1.

FIGS. 4 and 5 are cross-sectional views illustrating various embodiments of an opening part provided in a first protective layer of FIG. 1.

FIG. 6 is an enlarged cross-sectional view of a region R1 of FIG. 1 according to a second embodiment.

FIG. 7 is a cross-sectional view illustrating a semiconductor package according to a third embodiment.

FIG. 8 is a cross-sectional view illustrating a semiconductor package according to a fourth embodiment.

FIG. 9 is an enlarged cross-sectional view of a region R1 of FIG. 8.

FIG. 10 is a cross-sectional view illustrating a semiconductor package according to a fifth embodiment.

FIG. 11 is an enlarged cross-sectional view of a region R1 of FIG. 10.

FIG. 12 is a plan view illustrating the first protective layer and the molding member of FIG. 10.

FIG. 13 is a cross-sectional view illustrating a semiconductor package according to the sixth embodiment.

### BEST MODEL

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

In addition, the semiconductor device may be an integrated passive device (IPD). In addition, the semiconductor device may be a multilayer ceramic capacitor (MLCC) or a silicon-based capacitor.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### Circuit Board and Semiconductor Package

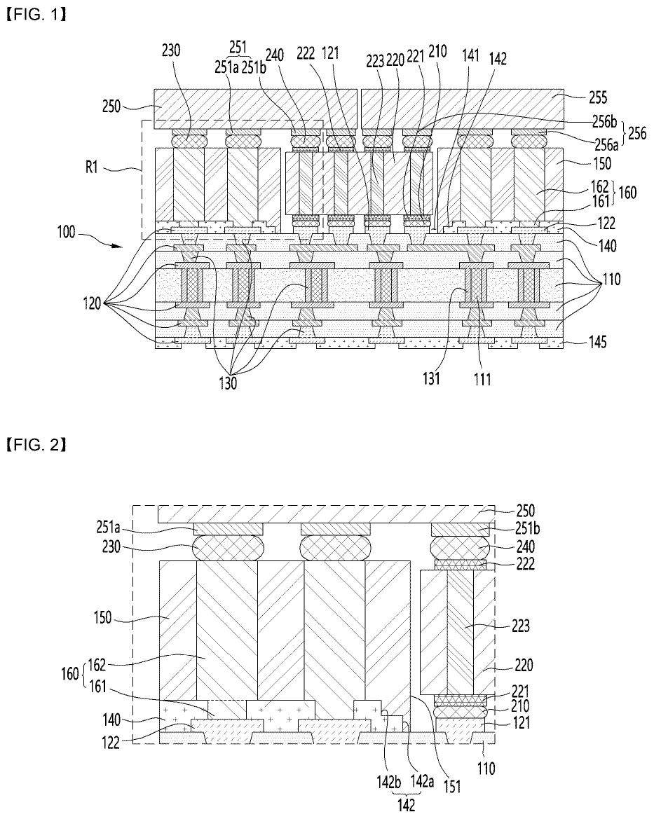

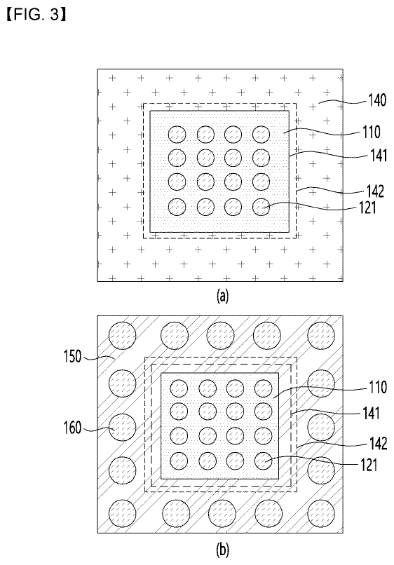

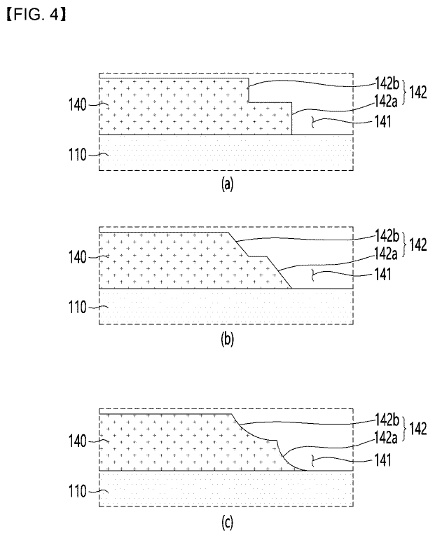

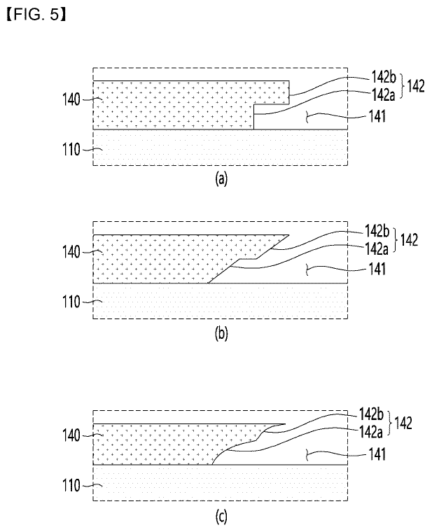

FIG. 1 is a cross-sectional view illustrating a semiconductor package according to a first embodiment, FIG. 2 is an enlarged cross-sectional view of a region R1 of FIG. 1, FIG. 3 is a plan view illustrating a first protective layer and a molding member of FIG. 1, and FIGS. 4 and 5 are cross-sectional views illustrating various embodiments of an opening part provided in a first protective layer of FIG. 1.

Referring to FIGS. 1 and 2, a semiconductor package includes a circuit board 100.

In one embodiment, the circuit board 100 may provide a space to which at least one external substrate is coupled. For example, the external substrate may refer to a main board provided in an electronic device. That is, the circuit board 100 of one embodiment may function to connect the main board of the electronic device with a plurality of semiconductor devices.

In another embodiment, the circuit board 100 may function to connect a package substrate connected to the main board of the electronic device with a plurality of semiconductor devices.

The circuit board 100 may electrically connect a connection member 220 and semiconductor devices 250 and 255, and electrically connect the connection member 220 and semiconductor devices 250 and 255 with the main board of the electronic device.

For example, the circuit board 100 can serve as a horizontal connection between a plurality of semiconductor devices and a vertical connection between the semiconductor devices and a package substrate and/or a main board.

A connection member 220 and semiconductor devices 250 and 255 are mounted on the circuit board 100. For example, the circuit board 100 may include a first pad part 121 and a conductive bonding part 160.

The connection member 220 may be mounted on the first pad part 121 of the circuit board 100. In addition, the semiconductor devices 250 and 255 may be mounted on the conductive bonding part 160 of the circuit board 100.

The connection member 220 and semiconductor devices 250 and 255 may have a stacked structure on the circuit board 100 in a vertical direction.

In one embodiment, the connection member 220 may be an active device. For example, the connection member 220 may function as a semiconductor device and electrically connect between the semiconductor device 250 and 255 and the circuit board 100. At this time, the connection member 220 may function as a logic chip and electrically connect between the semiconductor device 250 and 255 and the circuit board 100. Therefore, the connection member 220 may function as a logic chip and perform a signal transmission function between the semiconductor device 250 and 255 disposed thereon and the circuit board 100. Preferably, the connection member 220 may be a bridge die.

For example, functionally separated chiplet units of semiconductor devices, or a plurality of semiconductor devices 250 and 355 with different functions, such as a CPU and GPU, or a GPU and HBM, may be mounted on a circuit board 100., and the connection member 220 may electrically connect a plurality of semiconductor devices 250 and 355 to enable communication between the semiconductor devices.

In one embodiment, the connection member 220 may be an inorganic bridge. For example, the connection member 220 may be a silicon bridge. The connection member 220 may include a silicon substrate and a redistribution layer. For example, the connection member 220 may be formed of a same material as the semiconductor devices 250 and 255. If the connection member 220 is an inorganic bridge, the connection member may have a structure in which pads 221 and 222 provided on upper and lower surfaces of the connection member 220 are electrically connected via a through silicon via (TSV) 223.

In another embodiment, the connection member 220 is an organic bridge. For example, the connection member 220 may include an organic substrate in which the silicon substrate of the inorganic bridge is redisposed with an organic substrate. The organic substrate may include a photo-curable resin or a thermos-curable resin. If the connection member 220 is an organic bridge, pads 221 and 222 provided on the upper and lower surfaces of the connection member 220 may be electrically connected to each other via a through electrode 223 penetrating the connection member 220. Specifically, when the connection member 220 is an organic bridge, the connection member 220 may include a plurality of redistribution insulating layers, a plurality of redistribution pattern layers, and a plurality of redistribution via electrodes stacked along a vertical direction. For example, the redistribution insulating layer of the connection member 220 may have a build-up structure including a plurality of layers stacked along a vertical direction. In addition, the redistribution pattern layers may be disposed on each surface of the redistribution insulating layers formed in a plurality of layers. In addition, the redistribution via electrodes may electrically connect the redistribution pattern layers formed on surfaces of each redistribution insulating layer. Therefore, when the connection member 220 includes an organic material, the through electrode 223 described above may be understood to include a plurality of redistribution pattern layers spaced apart from each other along a vertical direction on a plurality of redistribution insulating layers having a build-up structure, and a plurality of via electrodes connecting the plurality of redistribution pattern layers formed on different layers.

The connection member 220 may be provided in a plurality of units spaced apart from each other in a horizontal direction on the circuit board 100. For example, semiconductor packages applied to servers, HPCs, and other devices require high electric power and/or multi-signal characteristics. Furthermore, semiconductor packages applied to servers, HPCs, and other devices may have three or more mounted semiconductor devices. In this case, a plurality of connection members 220 may be provided while being spaced horizontally on the circuit board 100.

The semiconductor package may include a first connecting part 210 disposed between a first pad part 121 of the circuit board 100 and a lower pad 221 of the connection member 220. The first connecting part 210 physically couples the connection member 220 to the circuit board 100 and electrically connects them.

The semiconductor package may include a second connecting part 230 disposed between the conductive bonding part 160 of the circuit board 100 and terminals 251 and 256 of the semiconductor devices 250 and 255. The conductive bonding part 160 can be used as a line for transmitting electric power and/or a power signal to the semiconductor device 250 and 255, and the second connecting part 230 can electrically connect between the conductive bonding part 160 and the semiconductor device 250 and 255. Through this, the embodiment can enable stable power and/or electric power supply to the semiconductor device 250 and 255 through the conductive bonding part 160, thereby enabling the semiconductor device 250 and 255 to operate stably. In particular, a number of power terminals and communication terminals of semiconductor packages applied to servers and/or HPCs (High Performance Computers) is increasing significantly, and accordingly, a circuit board with a high number of layers and a large area is required, and accordingly, a thickness of a core layer provided in a core board is also increasing. In accordance with this trend, it may be difficult to provide stable power and/or electric power supply to the semiconductor device 250 and 255, and the semiconductor device 250 and 255 may operate abnormally due to power and/or electric power shortage of the semiconductor device 250 and 255.

Accordingly, the embodiment includes a conductive bonding part 160, and can supply stable power and/or electric power to semiconductor devices 250 and 255 using the conductive bonding part 160.

For example, the first semiconductor device 250 includes a first group of terminals 251a overlapping the conductive bonding part 160 in a vertical direction and a second group of terminals 251b overlapping the upper pad 222 of the connection member 220 in the vertical direction. In addition, the second semiconductor device 255 includes a first group of terminals 256a overlapping the conductive bonding part 160 in the vertical direction and a second group of terminals 256b overlapping the upper pad 222 of the connection member 220 in the vertical direction. At this time, the first group of the terminals 251a and 256a may include power and/or electric power terminals among the plurality of terminals provided in the semiconductor device 250 and 255, and the second group of the terminals 251b, and 256b may include communication terminals among the plurality of terminals provided in the semiconductor device 250 and 260. Here, the communication terminals may include terminals for transmitting and receiving signals between the semiconductor devices 250 and 255 and terminals for transmitting and receiving signals between each of the semiconductor devices 250 and 255 and the circuit board 100.

At this time, the second connecting part 230 may be disposed between the conductive bonding part 160 and the terminals 251a and 256a of the first group of the semiconductor device 250 and 255. The second connecting part 230 can physically couple the semiconductor devices 250 and 255 to the conductive bonding part 160 of the circuit board 100 and electrically connect between the semiconductor devices 250 and 255 and the conductive bonding part 160 of the circuit board 100. In particular, the second connecting part 230 can stably couple the terminals 251a and 256a of the first group of the semiconductor devices 250 and 255 to the conductive bonding part 160, thereby ensuring stable power and/or electric power supply to the terminals 251a and 256a of the first group of the semiconductor devices 250 and 255. Therefore, the embodiment can solve a problem of power and/or electric power shortage of the semiconductor devices 250 and 255.

The semiconductor package may further include a third connecting part 240 disposed between an upper pad 222 of the connection member 220 and the second group of terminals 251b, and 256b of the semiconductor device 250 and 255. The third connecting part 240 physically connects the upper pad 222 of the connection member 220 to the second group of terminals 251b, and 256b of the semiconductor device 250 and 255, while electrically connecting between the upper pad 222 of the connection member 220 and the second group of terminals 251b, and 256b of the semiconductor device 250 and 255.

Accordingly, the semiconductor device 250 and 255 can receive power signals and/or electrical power from the conductive bonding part 160 of the circuit board 100 via the second connecting part 230. In addition, the semiconductor device 250 and 255 can exchange communication signals with the connection member 220 through the third connecting part 240. However, the embodiment is not limited thereto, and the semiconductor device 250 and 255 may also receive a common voltage and/or a common current through the connection member 220.

In this case, the semiconductor package may supply a power signal and/or electrical power to the semiconductor device 250 and 255 through the conductive bonding part 160, thereby providing sufficient power for driving the semiconductor device 250 and 255 or enabling smooth control of the power operation.

In particular, a number of power terminals and communication terminals of semiconductor packages applied to servers and/or HPCs (High Performance Computers) is increasing significantly, and accordingly, a circuit board with a high number of layers and a large area is required, and accordingly, a thickness of a core layer provided in a core board is also increasing. In accordance with this trend, it may be difficult to provide stable power and/or electric power supply to the semiconductor device 250 and 255, and the semiconductor device 250 and 255 may operate abnormally due to power and/or electric power shortage of the semiconductor device 250 and 255.

Accordingly, the embodiment includes a conductive bonding part 160, which can be used to ensure a stable power and/or electric power supply to the semiconductor devices 250 and 255.

In this case, the conductive bonding part 160 of the embodiment may perform a different function than pillars or post-bumps provided in typical PoP (Package on Package). For example, the pillar or post bump provided in the PoP functions to connect an upper package substrate and a lower package substrate. In contrast, the conductive bonding part 160 of the embodiment functions to transmit power and/or electric power to the semiconductor device 250 and 255. Furthermore, the semiconductor device 250 and 255 must be electrically connected not only to the conductive bonding part 160 but also to the connection member 220, and accordingly, the conductive bonding part 160 of the embodiment must be provided so that there is no height deviation from the upper pad 222 provided in the connection member 220.

Accordingly, the embodiment can more stably place the conductive bonding part 160 on the circuit board 100 by combining the arrangement structure of the molding member 150, the first protective layer 140, and the conductive bonding part 160 provided on the circuit board 100, can more stably supply power and/or electric power to the semiconductor device 250 and 255 through the conductive bonding part 160, and can minimize a height deviation between the conductive bonding part 160 and the upper pad 222 of the connection member 220.

Therefore, the embodiment can improve driving characteristics of the semiconductor device 250 and 255. That is, the embodiment can solve the problem of insufficient power provided to the semiconductor device 250 and 255. Furthermore, the embodiment can provide at least one of the power signal, electrical power, and communication signal of the semiconductor device 250 and 255 through different paths via the conductive bonding part 160, the second connecting part 230, and the third connecting part 240. Accordingly, the embodiment can solve a problem of loss of the communication signal caused by the power signal. For example, the embodiment can minimize mutual interference between the power signal and the communication signal. Therefore, the embodiment can enable the semiconductor package to operate more stably, and further, can enable a product such as a server including the semiconductor package to operate stably.

The first connecting part 210, the second connecting part 230, and the third connecting part 240 can electrically connect a plurality of components using at least one bonding method among wire bonding, solder bonding, and direct metal-to-metal bonding. That is, since the first connecting part 210, the second connecting part 230, and the third connecting part 240 have a function of electrically connecting a plurality of components, the connecting part can be understood as an electrically connected part, not solder or wire.

For example, the bonding of the present embodiment can adopt at least one of solder bonding and/or direct metal-to-metal bonding. The solder bonding method can electrically connect a plurality of components using a material including at least one of Sn, Ag, and Cu. In addition, the direct metal-to-metal bonding method may mean directly bonding a plurality of components by applying heat and pressure between them to cause recrystallization, without the use of solder, wires, conductive adhesives, etc. In addition, the direct metal-to-metal bonding method may refer to a bonding method using a first connecting part 210. In this case, the first connecting part 210 may refer to a metal layer formed between a plurality of components through recrystallization. In addition to solder bonding and direct metal-to-metal bonding, there are connection methods such as wire bonding. However, the wire bonding is not suitable for connecting to the conductive bonding part 160 for power transmission because the number of terminals to be connected is small and the resistance is large due to a thin thickness of the wire.

According to an embodiment, the semiconductor package may be applied to servers or HPC (High Performance Computing), and thus, the number of terminals capable of transmitting large amounts of power and signals may significantly increase compared to conventional packages. Accordingly, sizes and spacings of the first to third connecting parts 210, 230, and 240 may be smaller than those of a conventional package. Therefore, according to the present embodiment, the first connecting part 210, the second connecting part 230, and the third connecting part 240 may apply a solder bonding method, and a plurality of components may be connected to each other by a thermal compression bonding method, which is one of the solder bonding methods. The thermal compression bonding method refers to a method of directly connecting a plurality of components by applying heat and pressure to the first connecting part 210, the second connecting part 230, and the third connecting part 240. Through this, the circuit board 100 is electrically connected to the connection member 220 and the semiconductor device 250 and 255.

The circuit board 100 may include an insulating layer 110, a first electrode part 120, a second electrode part 130, a first protective layer 140, a second protective layer 145, a molding member 150, and a conductive bonding part 160. Here, the insulating layer 110, the first electrode part 120, the second electrode part 130, the first protective layer 140, and the second protective layer 145 of the circuit board 100 may be referred to as a build-up structure laminated along a vertical direction. In addition, the molding member 150 and the conductive bonding part 160 may be disposed on the build-up structure of the circuit board 100.

The insulating layer 110 can provide excellent processability, enable slimming of the substrate, and enable miniaturization of the electrode part (for example, the first electrode part 120) provided in the circuit board 100. Accordingly, the insulating layer 110 can include at least one of a photosensitive organic material that does not include a reinforcing member, a core insulating member that includes glass fiber as a reinforcing member, a resin insulating member that includes inorganic particles, and a resin insulating member that includes GCP (Glass Core Primer) as a reinforcing member. In one embodiment, the insulating layer that includes a reinforcing member can be provided as a core layer, and thus the circuit board can be provided as a core substrate.

For example, the insulating layer 110 can use ABF (Ajinomoto Build-up Film), a product released by Ajinomoto Co., Ltd., and the insulating layer 110 can be used FR-4, BT (Bismaleimide Triazine), PID (Photo Image-able Dielectric resin), BT, etc., but are not limited thereto.

The insulating layer 110 may be provided in a laminated form of a plurality of layers. As illustrated in FIG. 1, the insulating layer 110 may have a five-layer laminated structure, but is not limited thereto. For example, the insulating layer 110 may have a laminated structure of four or fewer layers, or six or more layers.

In one embodiment, a plurality of layers of the insulating layer 110 may be formed of a same insulating material. However, the embodiment is not limited thereto, and at least one of the plurality of layers of the insulating layer 110 may have an insulating material different from the other layers.

Through the laminated structure of the insulating layer 110 described above, the circuit board of the embodiment can electrically connect the semiconductor device and the main board.

By including a reinforcing member in at least one of the plurality of layers of the insulating layer 110, a rigidity of the circuit board 100 can be improved. For example, the reinforcing member can prevent the circuit board and semiconductor package from being significantly warped in a specific direction. Accordingly, the insulating layer 110 can be prevented from warping during a manufacturing process of the circuit board 100, thereby improving a positional accuracy of the first electrode part 120 and the second electrode part 130, and further improving an alignment between them. Furthermore, the semiconductor device can be stably coupled to the circuit board by ensuring the rigidity of the circuit board, thereby ensuring stable operation of the semiconductor device. Furthermore, products such as servers to which the semiconductor package of the embodiment is applied can be stably operated, thereby improving product reliability.

The circuit board 100 includes an electrode part. The electrode part includes a first electrode part 120, a second electrode part 130, and a conductive bonding part 160.

The first electrode part 120 can be horizontally disposed between each of the plurality of layers of the insulating layer 110, and the second electrode part 130 can be vertically disposed to penetrate each of the plurality of layers of the insulating layer 110.

The first electrode part 120 may include pads and/or traces. The pads of the first electrode part 120 may overlap the second electrode part 130 in the vertical direction, and thus may mean an electrode directly connected to the second electrode part 130. The trace of the first electrode part 120 may mean an elongated signal line connected to the pad of the first electrode part 120 and thus transmitting a signal between a plurality of pads.

The first electrode part 120 includes a pad part disposed on an outermost layer of the insulating layer 110. The pad part may mean a wiring electrode provided on an uppermost layer and a lowermost layer among the first electrode parts 120 provided in each layer of the insulating layer 110.

The first electrode part 120 includes a first pad part 121 and a second pad part 122.

The first pad part 121 and the second pad part 122 may refer to electrodes provided on the uppermost layer among the first electrode parts provided on each layer of the insulating layer 110. However, the embodiment is not limited thereto, and the first pad part 121 and the second pad part 122 may also refer to electrodes provided on a lowermost layer of the insulating layer 110 depending on a direction in which the semiconductor package is viewed.

The first pad part 121 and the second pad part 122 may be provided in different regions of an upper surface of the insulating layer 110 and spaced apart from each other in the horizontal direction. According to one embodiment, the different regions of the upper surface of the insulating layer 110 may be divided into an inner region that overlaps the connection member 220 in the vertical direction and an outer region that surrounds an outside of the connection member 220.

The first pad part 121 may be provided in the inner region of the upper surface of the insulating layer 110, and the second pad part 122 may be provided in the outer region of the upper surface of the insulating layer 110. A plurality of second pad parts 122 may be provided along a perimeter of the insulating layer 110 in the outer region of the upper surface of the insulating layer 110.

A width of the second pad part 122 in the horizontal direction may be greater than the width of the first pad part 121 in the horizontal direction. For example, the second pad part 122 is a pad to which the conductive bonding part 160 is bonded, and may function as a signal line that supplies a power signal and/or electric power to the semiconductor device 250 and 255. The width of the first pad part 121 may correspond to a width of the lower pad 221 provided in the connection member 220.

In an embodiment, a second pad part 122 having a wider width than the first pad part 121 may be provided in the outer region of the upper surface of the insulating layer 110 surrounding the first pad part 121, and widths of the first and second pad parts 121 and 122 may be different from the width of the pad part 120 disposed on the lower surface of the insulating layer 110. That is, since the widths of the pad parts 120, 121, and 122 disposed on the upper and lower surfaces of the insulating layer 110 are different from each other, the insulating layer 110 may be prevented from being significantly warped in a specific direction.

For example, the circuit board may be warped to have a convex or concave shape depending on a thickness of each layer of the insulating layer 110, properties of each layer of the insulating layer 110, a wiring density of the first electrode part 120 provided on each layer of the insulating layer 110, etc. In addition, when the circuit board is warped in a specific direction, the first pad part 121 and the second pad part 122 provided on the circuit board may have different heights, and thus, the connection member 220 and the semiconductor device 250 and 255 may not be stably coupled on the circuit board 100.

For example, the second pad part 122 may prevent the insulating layer 110 from being warped into a convex shape and/or a concave shape. For example, the embodiment allows the second pad part 122 to have a width greater than the width of the first pad part 121, and allows the widths of the first and second pad parts 121 and 122 to be different from the width of the pad part 120 disposed on the lower surface of the insulating layer 110 to ensure rigidity in the outer region of the upper surface of the insulating layer 110 by the second pad part 122. Accordingly, the embodiment can prevent the circuit board from being significantly warped in a specific direction, and can stably mount the semiconductor device on the circuit board. For example, the embodiment may allow the second pad part 122 having a larger width than the pad part 120 disposed on the lower surface of the insulating layer 110 and the width of the first pad part 121 disposed in the inner region of the upper surface of the insulating layer 110 to be disposed in the outer region of the upper surface of the insulating layer 110, and may prevent both ends of the circuit board 100 from being warped in an upward direction and/or a downward direction. However, since a warpage direction of the insulating layer 110 may vary depending on the size of the circuit board, the number of laminated insulating layers 110, and the type of insulating layer constituting the insulating layer 110, it can be freely designed without being limited to the embodiment.

Accordingly, the embodiment arranges the first pad part 121 in the inner region of the upper surface of the insulating layer 110, while the second pad part 122 is disposed along a circumferential direction of an upper surface of the insulating layer 110 in the outer region of the upper surface of the insulating layer 110 surrounding the first pad part 121. Through this, the embodiment can prevent the circuit board from being significantly warped in a specific direction by using the second pad part 122 having a relatively large width, thereby enabling the semiconductor device to be stably disposed on the circuit board. Therefore, the embodiment can enable the semiconductor device to operate stably, thereby enabling the stable operation of semiconductor packages and products such as servers to which the semiconductor package is applied.

In addition, the embodiment can prevent the circuit board from being significantly warped in a specific direction while enabling a process of mounting the semiconductor device to be smoothly performed, by arranging the first pad part 121 and the second pad part 122. Therefore, the embodiment can reduce the difficulty of a process of mounting the semiconductor device, thereby improving product yield, and further solving the electrical short circuit problem and/or electrical opening problem between the first pad part 121 and the lower pad 221 of the connection member 220.

The second electrode part 130 may be formed by filling through holes formed in a plurality of layers of the insulating layer 110 with a conductive material. The second electrode part 130 is connected to the first electrode part 120. The second electrode part 130 may vertically connect wiring electrodes formed in different layers.

In addition, the circuit board 100 may include a conductive bonding part 160. The conductive bonding part 160 may be disposed on the second pad part 122. The conductive bonding part 160 may be formed to surround the first pad part 121. For example, a conductive bonding part 160 may be provided surrounding the first pad part 121, and may be provided in multiple numbers spaced apart from each other along the circumferential direction of the upper surface of the insulating layer 110.

An upper surface of the conductive bonding part 160 may be positioned on a same plane as the upper surface of the upper pad 222 of the connection member 220. Here, being positioned on a same plane may mean that a height difference between an upper surface of the conductive bonding part 160 and an upper surface of the upper pad 222 of the connection member 220 is 10 μm or less, or 8 μm or less, or 5 μm or less, or 2 μm or less. In particular, the conductive bonding part 160 may be stably disposed on the circuit board 100 by combination with the structures of the first protective layer 140 and the molding member 150, and further may be disposed on a same plane as the upper pad 222 of the connection member 220. This is because the conductive bonding part 160 can be firmly fixed and/or bonded by the first protective layer 140 and the molding member 150, thereby solving reliability problems such as peeling and/or cracking of the conductive bonding part 160 and allowing the conductive bonding part 160 to have a same height as the upper pad 222 of the connection member 220.

To this end, a thickness of the conductive bonding part 160 in the vertical direction may be greater than a thickness in the vertical direction of the through electrode 230 provided in the connection member 220. For example, the conductive bonding part 160 may be greater than a sum of thicknesses in the vertical direction of a plurality of redistribution via electrodes provided in each of the different redistribution insulating layers of the connection member 220. Accordingly, a height of the conductive bonding part 160 may be higher than a height of the connection member 220. For example, an upper surface of the conductive bonding part 160 may be positioned higher than an upper surface of the connection member 220. Accordingly, the embodiment may enable stable power to be supplied to the semiconductor device 250 and 255 through the conductive bonding part 160. In addition, the embodiment can enable the mounting of the semiconductor devices 250 and 255 while the semiconductor devices 250 and 255 are stably supported by the conductive bonding part 160.

The conductive bonding part 160 can space the connection member 220 and the semiconductor devices 250 and 255 in the vertical direction during the process of mounting the semiconductor devices 250 and 255, and accordingly, the semiconductor devices 250 and 255 may be stably mounted.

The conductive bonding part 160 can penetrate the first protective layer 140 and the molding member 150, which will be described later.

In one embodiment, when the conductive bonding part 160 penetrates the molding member 150, an upper surface of the conductive bonding part 160 may be positioned on a same plane as the upper surface of the molding member 150, or the upper surface of the conductive bonding part 160 may be positioned higher than the upper surface of the molding member 150.

Although the conductive bonding part 160 penetrates the molding member 150, the embodiment is not limited thereto. For example, the conductive bonding part 160 may penetrate a portion of the molding member 150. In this case, the upper surface of the conductive bonding part 160 may be disposed lower than the upper surface of the molding member 150, and the molding member 150 may include an opening that overlaps the upper surface of the conductive bonding part 160 in the vertical direction.

The conductive bonding part 160 may be divided into a plurality of through parts along the vertical direction. For example, the conductive bonding part 160 may include a first through part 161 and a second through part 162.

The first through part 161 of the conductive bonding part 160 may penetrate a first protective layer 140 provided on a second pad part 122. The second through part 162 of the conductive bonding part 160 may penetrate a molding member 150 provided on the first protective layer 140.

A width of the first through part 161 in the horizontal direction may be different from a width of the second through part 162 in the horizontal direction, and thus, side surfaces of the first through part 161 and the second through part 162 may have a step. In one embodiment, the width of the first through part 161 may be smaller than the width of the second through part 162. For example, the width of the upper surface of the conductive bonding part 160 connected to the terminals 251a and 256a of the first group of the semiconductor device 250 and 255 may be greater than the width of the lower surface of the conductive bonding part 160 connected to the second pad part 122. When the width of the first through part 161 and the width of the second through part 162 are disposed to be the same, if a pattern for arranging the conductive bonding part 160 is misaligned with a position of the second pad part 122, a contact area between the second pad part 122 and the conductive bonding part 160 may become narrow. Accordingly, since a resistance in supplying power and/or signals may increase, signal and/or power loss may increase. The conductive bonding part 160 may be used as a wiring line for supplying power signals and/or electrical power to the semiconductor device 250 and 255, and accordingly, an overall resistance may be reduced because the width of the conductive bonding part 160 is greater than the width of the second pad part 122. Therefore, the embodiment may increase an intensity of the power or electric power supplied to the semiconductor device 250 and 255 compared to a case where a width of the first through part 161 and a width of the second through part 162 are disposed to be the same. Through this, the embodiment may enable the semiconductor device 250 and 255 to operate more stably, and may improve the operational reliability of the semiconductor package.

The circuit board 100 may include a first protective layer 140 and a second protective layer 145.

For example, the first protective layer 140 and the second protective layer 145 may be solder resist layers containing organic polymer materials. Since the solder resist layer has poor wettability with solder, it can protect the circuit board 100 from electrical short circuit problems caused by contact between solders disposed on each pad part, and can protect the insulating layer 110 from external contaminants such as moisture or particles that may be exposed during the process. For example, the first protective layer 140 and the second protective layer 145 may contain an epoxy acrylate series resin. In detail, the first protective layer 140 and the second protective layer 145 may contain a resin, a curing agent, a photoinitiator, a pigment, a solvent, a filler, an additive, an acrylic series monomer, etc. However, the embodiment is not limited thereto, and the first protective layer 140 and the second protective layer 145 may be any one of a photo solder resist layer, a cover-lay, and a polymer material.

The first protective layer 140 may be provided on the upper surface of the insulating layer 110. In addition, the second protective layer 145 may be provided on the lower surface of the insulating layer 110.

The first protective layer 140 may include at least one opening part 141. For example, the first protective layer 140 may include an opening part 141 overlapping the semiconductor device 250 and 255 and/or the first pad part 121 in the vertical direction.

In one embodiment, the opening part 141 may penetrate the upper and lower surfaces of the first protective layer 140. In this case, the opening part 141 may be referred to as a through hole penetrating the first protective layer 140.

A plurality of opening parts 141 may be provided. For example, a plurality of first pad parts 121 may be provided, and a plurality of opening parts 141 may be provided so as to overlap each of the plurality of first pad parts in the vertical direction. However, the embodiment is not limited thereto, and one opening part 141 may be provided to overlap a plurality of first pad parts in a vertical direction as a whole.

A side wall 142 of the opening part 141 of the first protective layer 140 may have a step. For example, the first protective layer 140 may be provided along the circumferential direction of a region where the first pad part 121 is disposed, and may have a side wall 142 with a step.

For example, the side wall 142 of the opening part 141 of the first protective layer 140 may include a first part 142a adjacent to the lower surface of the first protective layer 140, and a second part 142b disposed on the first part 142a and having a step from the first part 142a.

For example, in the opening part 141 of the first protective layer 140, a width of the first part 142a in the horizontal direction may be different from a width of the second part 142b in the horizontal direction.

For example, the first part 142a of one embodiment may have a slope whose width does not change from the upper surface of the first protective layer 140 toward the lower surface of the first protective layer 140. The second part 142b of one embodiment may have a slope whose width does not change from the upper surface of the first protective layer 140 toward the lower surface of the first protective layer 140. At this time, the width of the opening part 141 of the first protective layer 140 in the first part 142a may be different from the width of the opening part 141 of the first protective layer 140 in the second part 142b. For example, the width of the opening part 141 of the first protective layer 140 in the first part 142a may be smaller than the width of the opening part 141 of the first protective layer 140 in the second part 142b. That is, the side wall 142 of the opening part 141 of the first protective layer 140 may include a first part 142a and a second part 142b having a step.

Accordingly, the embodiment can improve the physical reliability of the first protective layer 140. For example, the first protective layer 140 may expand and/or contract due to heat cycles. At this time, the first protective layer 140 may warp due to the heat cycle resulting from the expansion and/or contraction, which may cause a physical reliability issue in which the first protective layer 140 is peeled off from the insulating layer 110. In an embodiment, the side wall 142 of the opening part 141 of the first protective layer 140 has a step including a first part 142a and a second part 142b. In this case, a surface area of the side wall 142 with the step may be larger than that of the side wall without the step. In this case, when the surface area of the side wall 142 is large, a flow range of the first protective layer 140 can be further increased during expansion and/or contraction, thereby minimizing thermal deformation of the first protective layer 140 due to expansion and/or contraction. Therefore, the embodiment can resolve the physical reliability issue of the first protective layer 140 peeling from the insulating layer 100, thereby ensuring stable protection of the insulating layer 110 and an electrode part through the protective layer.

In particular, the first protective layer 140 can improve the adhesion with the molding member 150 by including the opening part 141 having a step, and the conductive bonding part 160 can be molded more stably by the molding member 150. Accordingly, the embodiment can enable more stable power and/or electric power supply to the semiconductor device 250 and 255 through the conductive bonding part 160, and can minimize the height deviation between the conductive bonding part 160 and the upper pad 222 of the connection member 220.

The circuit board 100 or semiconductor package may include a molding member 150. The molding member 150 may be an epoxy mold compound (EMC), but is not limited thereto.

The molding member 150 may be disposed on the first protective layer 140. The molding member 150 may be provided to cover the upper surface of the first protective layer 140. In addition, the molding member 150 may overlap at least a portion of the opening part 141 provided on the first protective layer 140 in the vertical direction. For example, the molding member 150 may be provided to cover the side wall 142 of the first protective layer 140. Preferably, the molding member 150 may contact the step between the first part 142a and the second part 142b of the side wall 142 of the first protective layer 140.

At this time, the molding member 150 may contact the step of the side wall 142 of the first protective layer 140, thereby increasing the contact area between the molding member 150 and the first protective layer 140. Therefore, the embodiment can improve the bonding strength between the molding member 150 and the first protective layer 140, and ensure that the molding member 150 is firmly bonded to the first protective layer 140.

Furthermore, the molding member 150 can mold the conductive bonding part 160. For example, the molding member 150 can be provided in an outer region of an upper portion of the circuit board 100, and can be molded the conductive bonding part 160. At this time, the molding member 150 can come into contact with the step of the side wall 142 of the first protective layer 140, and thus the conductive bonding part 160 can be molded while being firmly bonded on the first protective layer 140. Therefore, the embodiment can enable the conductive bonding part 160 to be more stably protected through the molding member 150, and thereby enable the semiconductor device 250 and 255 connected to the conductive bonding part 160 to operate more stably. For example, the embodiment can enable the conductive bonding part 160 to supply stable power and/or electric power to the semiconductor device 250 and 255, thereby improving the operational reliability of the semiconductor device 250 and 255.

For example, referring to (a) of FIG. 3, the first pad part 121 is disposed on the insulating layer 110. At this time, the first protective layer 140 includes an opening part 141 overlapping the first pad part 121 in the vertical direction. In addition, the side wall 142 of the opening part 141 of the first protective layer 140 may be provided along the circumferential direction of a region where the first pad part 121 is disposed. At this time, the first part 142a and the second part 142b of the side wall 142 of the first protective layer 140 may have a step.

In addition, referring to (b) of FIG. 3, a molding member 150 may be disposed on the first protective layer 140. At this time, the molding member 150 may mold the conductive bonding part 160. In addition, the molding member 150 may have an open region that overlaps the first pad part 121 in a vertical direction. For example, the molding member 150 may be spaced apart from the connection member 220 disposed on the first pad part 121, and may be disposed to mold the conductive bonding part 160 along the circumferential direction of a side surface of the connection member 220. At this time, the molding member 150 may overlap at least a portion of the opening part 141 provided on the first protective layer 140 in a vertical direction.

For example, the molding member 150 may be provided to fill at least a portion of the opening part 141 provided in the first protective layer 140.

Therefore, the molding member 150 may be in contact with the side wall 142 of the opening part 141 provided in the first protective layer 140. That is, the molding member 150 may be in contact with the first part 142a and the second part 142b of the side wall 142 of the opening part 141 provided in the first protective layer 140. Through this, the embodiment can improve the contact area between the molding member 150 and the first protective layer 140, thereby allowing the molding member 150 to be firmly bonded onto the first protective layer 140. Furthermore, the embodiment can enable the conductive bonding part 160 to be more stably protected through the molding member 150, thereby enabling the semiconductor device 250 and 255 connected to the conductive bonding part 160 to operate more stably. For example, the embodiment can enable the conductive bonding part 160 to supply stable power and/or electric power to the semiconductor device 250 and 255, thereby improving the operational reliability of the semiconductor device 250 and 255.

Furthermore, in one embodiment, the molding member 150 is provided to cover the side wall 142 of the opening part 141 of the first protective layer 140. Through this, the molding member 150 can mold not only the conductive bonding part 160 but also the side wall 142 of the first protective layer 140. For example, the molding member 150 can mold the conductive bonding part 160 while firmly bonding and fixing the first protective layer 140 on the insulating layer 110. Therefore, the embodiment can minimize the stress caused by the heat cycle due to expansion and/or contraction of the first protective layer 140 from being transferred to the conductive bonding part 160, thereby further improving the physical reliability and/or electrical reliability of the semiconductor package.

Meanwhile, the step of the side wall 142 of the opening part 141 provided in the first protective layer 140 may be modified in various forms.

For example, referring to (a) to (c) of FIG. 4, the opening part 141 provided in the first protective layer 140 may have a slope with a step that decreases in width from the upper surface to the lower surface of the first protective layer 140.

Referring to (a) of FIG. 4, the side wall 142 of the opening part 141 of the first protective layer 140 may include a first part 142a and a second part 142b having a step. In this case, each of the first part 142a and the second part 142b may be perpendicular to the upper or lower surface of the insulating layer 110. For example, a step of the side wall 142 of the opening part 141 of the first protective layer 140 of one embodiment may have a step shape.

Referring to FIG. 4(b), the side wall 142 of the opening part 141 of the first protective layer 140 may include a first part 142a and a second part 142b having a step. In this case, each of the first part 142a and the second part 142b may have a slope such that the width of the opening part 141 gradually decreases from the upper surface to the lower surface of the first protective layer 140. For example, the first part 142a and the second part 142b may be provided in the form of straight lines having a constant slope. In this case, the bonding strength between the first protective layer 140 and the molding member 150 can be further improved compared to (a) of FIG. 4, thereby further improving the physical reliability and/or electrical reliability of the semiconductor package.

Referring to (c) of FIG. 4, the side wall 142 of the opening part 141 of the first protective layer 140 may include a first part 142a and a second part 142b having a step. At this time, each of the first part 142a and the second part 142b may have a slope such that the width of the opening part 141 decreases from the upper surface to the lower surface of the first protective layer 140. At this time, the first part 142a and the second part 142b may be curved surfaces having a specific curvature. In this case, the bonding strength between the first protective layer 140 and the molding member 150 can be further improved compared to (a) and (b) of FIG. 4, thereby further improving the physical and/or electrical reliability of the semiconductor package.

Furthermore, if the side wall 142 of the opening part 141 of the first protective layer 140 has a curved surface, the stress caused by expansion and/or contraction of the first protective layer 140 due to heat cycles can be minimized, thereby further improving the physical and/or electrical reliability of the semiconductor package. For example, if the side wall of the opening part has a structure shown in (a) of FIG. 4, the edge portion where different slopes meet is bent at an angle close to a right angle, as a result, there may be a problem that the stress is concentrated in the bent edge portion. In contrast, when the side wall 142 of the opening part 141 of the first protective layer 140 has a curved surface, stress can be prevented from being concentrated at the edge portion, and further, stress can be evenly distributed throughout an entire region of the side wall 142 of the opening part 141.

In addition, referring to (a) to (c) of FIG. 5, the opening part 141 provided in the first protective layer 140 may have a slope with a step while its width increases from the upper surface to the lower surface of the first protective layer 140.

Referring to (a) of FIG. 5, the side wall 142 of the opening part 141 of the first protective layer 140 may include a first part 142a and a second part 142b having a step. At this time, each of the first part 142a and the second part 142b may be perpendicular to the upper or lower surface of the insulating layer 110. For example, the step of the side wall 142 of the opening part 141 of the first protective layer 140 of one embodiment may have a step shape. At this time, in the case of (a) of FIG. 5, the step between the first part 142a and the second part 142b may have a recessed shape that is sunken in the horizontal direction, thereby further improving the bonding strength with the molding member 150. For example, the step between the first part 142a and the second part 142b may function as an anchor that improves the bonding strength with the molding member 150.

Referring to (b) of FIG. 5, the side wall 142 of the opening part 141 of the first protective layer 140 may include a first part 142a and a second part 142b having a step. At this time, each of the first part 142a and the second part 142b may have a slope such that the width of the opening part 141 gradually increases from the upper surface to the lower surface of the first protective layer 140. For example, the first part 142a and the second part 142b may be provided in a form of a straight line having a certain slope. In this case, the bonding strength between the first protective layer 140 and the molding member 150 can be further improved compared to (a) of FIG. 5, thereby further improving the physical reliability and/or electrical reliability of the semiconductor package.

Referring to (c) of FIG. 5, the side wall 142 of the opening part 141 of the first protective layer 140 may include a first part 142a and a second part 142b having a step. At this time, each of the first part 142a and the second part 142b may have a slope such that the width of the opening part 141 decreases from the upper surface to the lower surface of the first protective layer 140. At this time, the first part 142a and the second part 142b may be curved surfaces having a specific curvature. In this case, the bonding strength between the first protective layer 140 and the molding member 150 can be further improved compared to (a) and (b) of FIG. 5, thereby further improving the physical reliability and/or electrical reliability of the semiconductor package.

Furthermore, when the side wall 142 of the opening part 141 of the first protective layer 140 is curved, stress caused by expansion and/or contraction of the first protective layer 140 due to heat cycles can be minimized, thereby further improving the physical and/or electrical reliability of the semiconductor package. For example, when the side wall 142 of the opening part 141 of the first protective layer 140 is curved, it is possible to prevent the stress from being concentrated in the edge portion, and furthermore, the stress may be evenly distributed throughout an entire region of the sidewall 142 of the opening 141.

Meanwhile, the first protective layer 140 and the molding member 150 may comprise different materials, but are not limited thereto. For example, the first protective layer 140 may be a solder resist layer, and the molding member 150 may be an epoxy mold compound layer, but are not limited thereto.

For example, the first protective layer 140 and the molding member 150 may comprise a same insulating material, and an interface between them may not be distinct. Therefore, the embodiment may simplify a manufacturing process by forming the first protective layer 140 and the molding member 150 of a same material, thereby improving the product yield.

Meanwhile, as a modified example of the embodiment of FIG. 2, a thickness of the conductive bonding part 160 may be different from a thickness of the connection member 220. Furthermore, a height of the conductive bonding part 160 may be greater than a height of the connection member 220. For example, the height of the conductive bonding part 160 may be greater than the height of the upper pad 222 disposed in the connection member 220. For example, the upper surface of the conductive bonding part 160 may be positioned higher than the upper surface of the upper pad 222 disposed in the connection member 220. Through this, the conductive bonding part 160 may be provided to surround the side portion of the connection member 220 while having a height greater than the height of the connection member 220. Therefore, the embodiment can more stably protect the connection member 220 through the conductive bonding part 160, thereby further improving the rigidity of the circuit board and the semiconductor package including the same, and further minimizing the stress applied to the connection member 220. Therefore, the embodiment can enable the semiconductor device 250 and 255 to operate more stably, and further improve the operational reliability of the semiconductor package.

Furthermore, as another modified example of the embodiment of FIG. 2, the molding member 150 and the conductive bonding part 160 can form a separate structure from the circuit board 100. For example, the embodiment can provide a molding structure including the conductive bonding part 160 and the molding member 150 that molds the conductive bonding part 160 separately from the circuit board 100. In this case, a contacting member (e.g., solder) may be disposed on the second pad part 122 of the circuit board 100. Furthermore, the separately manufactured molding structure described above may be bonded to the circuit board 100 via the contacting member disposed on the second pad part 122. In this case, the embodiment can minimize the stress transmitted to the circuit board during the process of forming the molding member 150, thereby resolving physical and/or electrical reliability issues of the circuit board. Furthermore, the embodiment can facilitate the process of manufacturing the molding structure by providing a separate molding structure, thereby further improving product yield.

FIG. 6 is an enlarged cross-sectional view of a region R1 of FIG. 1 according to a second embodiment.

Referring to FIG. 6, the conductive bonding part 160a includes a first through part 161a and a second through part 162.

The first through part 161a of the conductive bonding part 160a may penetrate the first protective layer 140 provided on the first pad part 121. The second through part 162a of the conductive bonding part 160a may penetrate the molding member 150 provided on the first protective layer 140.

A width of the first through part 161a in the horizontal direction may be different from a width of the second through part 162a in the horizontal direction, and thus, the side surfaces of the first through part 161a and the second through part 162a may have a step.

In one embodiment, the width of the first through part 161a may be greater than the width of the second through part 162a. For example, the width of the upper surface of the conductive bonding part 160a, which is connected to the first group of terminals 251a and 256a of the semiconductor device 250 and 255, may be greater than the width of the lower surface, which is connected to the second pad part 122. That is, the width of the second through part 162 of the conductive bonding part 160a of the second embodiment may be reduced while maintaining the width of the first through part 161a, compared to FIG. 2.

Accordingly, a pitch of the plurality of conductive bonding parts 160a may be reduced, and accordingly, a number of conductive bonding parts 160a disposed on the circuit board 100 may be increased. Thus, the embodiment enables the arrangement of the conductive bonding parts 160a corresponding to the increase in the number of terminals 251 of the first group of the semiconductor device 250 and 255, thereby improving circuit integration. Furthermore, the embodiment can be applied when a relatively small power level and/or power is required, or when the number of semiconductor devices disposed on a circuit board increases. Accordingly, the embodiment can reduce a spacing distance between the plurality of conductive bonding parts 160a, increase a number of the plurality of conductive bonding parts 160a disposed within a limited space, thereby enabling more stable power and/or electrical power supply to the plurality of semiconductor devices.

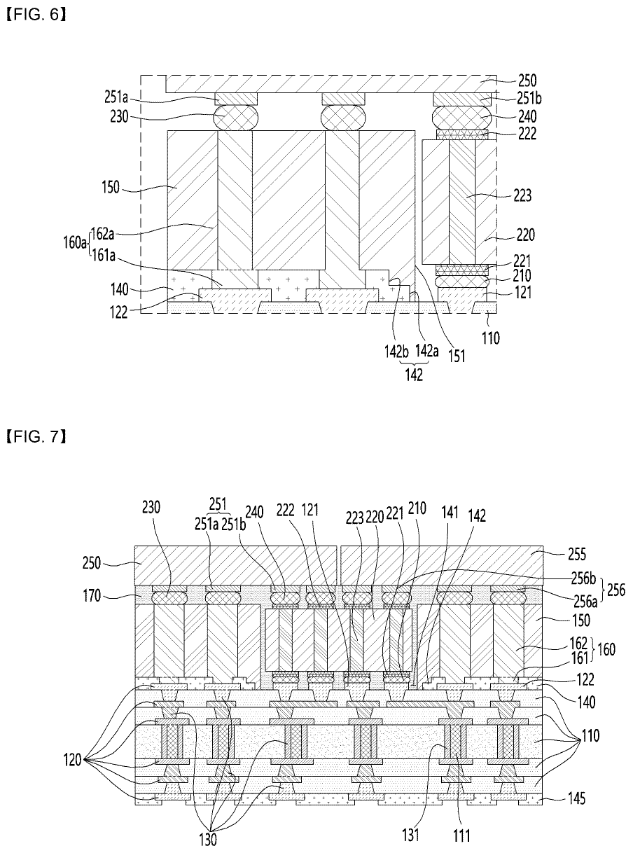

FIG. 7 is a cross-sectional view illustrating a semiconductor package according to a third embodiment.

Referring to FIG. 7, the semiconductor package may include a molding member. The molding member includes a first molding member 150 and a second molding member 170. The first molding member 150 corresponds to the molding member 150 illustrated in FIGS. 1 and 2, and thus, a detailed description thereof will be omitted.

The semiconductor package may further include a second molding member 170. The second molding part 170 may be provided to fill an open region of the first molding part 150. For example, the second molding part 170 may be provided to mold around the connection member 220. In addition, the second molding part 170 may mold a region between the circuit board 100 including the second connecting part 230 and the third connecting part 230 and the semiconductor device 250 and 255, and a region between the connection member 220 and the circuit board 100. The second molding part 170 may be an underfill. The embodiment may additionally include the second molding part 170, and accordingly, the connection member 220 and the semiconductor devices 250 and 255 may be more stably protected, and thus operation characteristics of the semiconductor package may be improved.

However, although FIG. 7 shows that a second molding part 170 is additionally provided, if the first molding part 150 and the second molding part 170 includes a same material, an interface between them may not be distinguished.

In addition, an inner side wall of the first molding part 150 may be spaced apart from an outer side wall of the connection member 220 by a predetermined horizontal distance. For example, the first molding part 150 and the connection member 220 may not directly contact each other and may be spaced apart from each other by a predetermined horizontal distance. For example, the first molding part 150 may be provided to surround the periphery of the connection member 220 at a position spaced apart from the connection member 220 by a predetermined horizontal distance. Accordingly, the embodiment can ensure that the second molding part 170 flows stably in a space corresponding to the horizontal distance described above, and thus molding processability and/or molding characteristics of the second molding part 170 can be further improved.

At this time, a horizontal distance between the inner side wall of the first molding part 150 and the outer side wall of the connection member 220 may be smaller than a width of the conductive bonding part 160 in the horizontal direction. Furthermore, the horizontal distance between the inner side wall of the first molding part 150 and the outer side wall of the connection member 220 may be larger than the width of the through electrode 223 provided in the connection member 220 in the horizontal direction. For example, the horizontal distance between the inner side wall of the first molding part 150 and the outer side wall of the connection member 220 may be smaller than the width of the conductive bonding part 160 in the horizontal direction and larger than the width of the through electrode 223 of the connection member 220 in the horizontal direction. Therefore, the embodiment can improve process characteristics while shortening a process time in a process of forming the second molding part 170, thereby further improving the product yield. In addition, the embodiment can solve a problem that a space between the first molding part 150 and the connection member 220 is not completely filled with the second molding member 170.

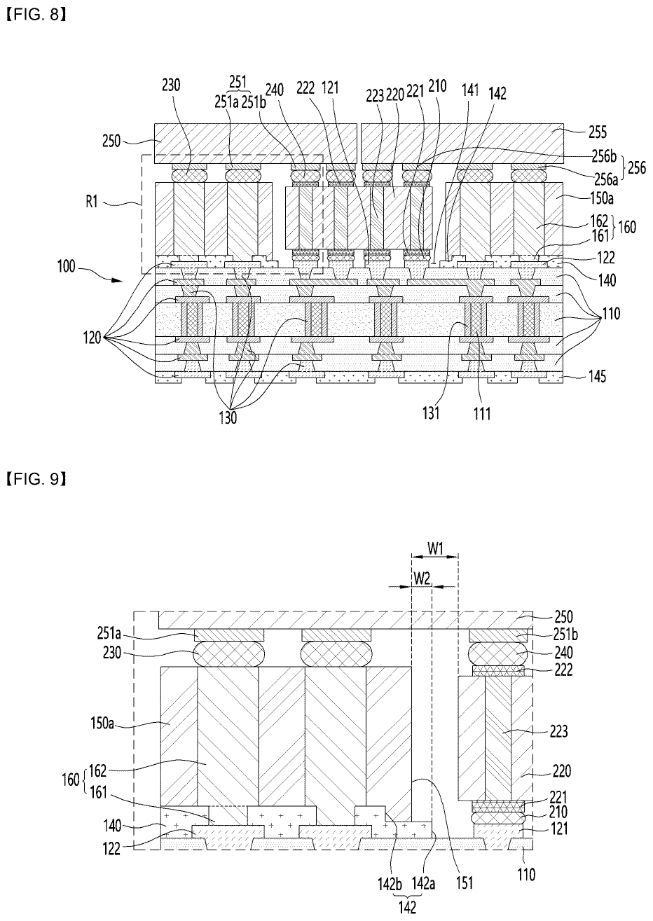

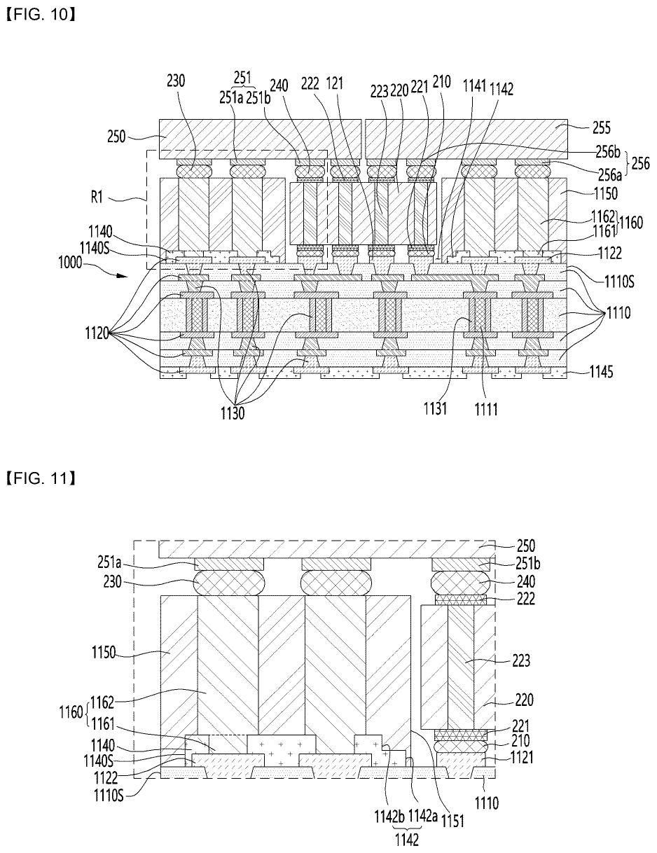

FIG. 8 is a cross-sectional view illustrating a semiconductor package according to a fourth embodiment, and FIG. 9 is an enlarged cross-sectional view of a region R1 of FIG. 8.

Referring to FIGS. 8 and 9, the semiconductor package may include a circuit board 100, a connection member 220, semiconductor devices 250 and 255, a first connecting part 210, a second connecting part 230, and a third connecting part 230.

At this time, the semiconductor package of the fourth embodiment may differ from the semiconductor package of the first embodiment of FIG. 1 in an arrangement structure of a molding member 150a provided in the circuit board 100.

The molding member 150a may be disposed on the first protective layer 140 while molding the conductive bonding part 160. The first protective layer 140 may include an opening part 141 including a side wall 142 of a first part 142a and a second part 142b having a step. Although omitted in FIGS. 8 and 9, the semiconductor package of the fourth embodiment may include the second molding part 170 illustrated in FIG. 8.

In this case, the molding member 150a may not overlap the opening part 141 of the first protective layer 140 in the vertical direction. For example, the molding member 150a may contact a portion of the side wall 142 of the opening part 141 of the first protective layer 140. For example, the molding member 150a may be in contact with a portion of the step of the side wall 142 of the first protective layer 140. That is, the molding member 150a may be in contact with the second part 142b of the side wall 142 of the first protective layer 140, and may not be in contact with the first part 142a. That is, since the side wall 142 of the first protective layer 140 has a step, even if the molding member 150a is in contact only with the second part 142b, it is possible to secure bonding strength between the first protective layer 140 and the molding member 150a. Accordingly, the embodiment can reduce the amount of the molding member 150a, thereby reducing the unit price of the product.

For example, the connection member 220 may have an outer side surface, and a first part 142a of a side wall 142 of an opening part 141 of a first protective layer 140 may be provided along a circumferential direction of the outer side surface of the connection member 220. In addition, the molding member 150a may include a side wall 151 that surrounds the outer side surface of the connection member 220 at a position spaced apart from the outer side surface of the connection member 220 by a first horizontal distance W1. The side wall 151 of the molding member 150a may be located further from the outer side surface of the connection member 220 than the first part 142a of the side wall 142 of the first protective layer 140. For example, the side wall 151 of the molding member 150a may be disposed spaced apart from the outer side surface of the connection member 220 by a first horizontal distance W1. In addition, the first part 142a of the side wall 142 of the first protective layer 140 may be disposed spaced apart from the outer side surface of the connection member 220 by a second horizontal distance. The second horizontal distance may be smaller than the first horizontal distance W1. For example, the first part 142a of the side wall 142 of the first protective layer 140 may be disposed closer to the outer side surface of the connection member 220 by a second horizontal distance W2 than the side wall 151 of the molding member 150a.

In this case, the first horizontal distance W1 may be smaller than the width of the conductive bonding part 160 in the horizontal direction. In addition, the first horizontal distance W1 may be greater than the width of the through electrode 223 provided in the connection member 220 in the horizontal direction. When the first horizontal distance W1 is greater than the width of the conductive bonding part 160 in the horizontal direction, a process time in a process of additionally molding the second molding part 170 may increase, and thus the yield in the process of molding the space between the molding member 150a and the connection member 220 with the second molding part 170 may deteriorate. For example, when the first horizontal distance W1 is greater than the width of the conductive bonding part 160 in the horizontal direction, the space between the molding member (150a, or the first molding part) and the connection member 220 may not be completely filled with the second molding part 170. In addition, the first horizontal distance W1 may be greater than the width in the horizontal direction of the through electrode 223 provided in the connection member 220. For example, the through electrode 223 may refer to a TSV provided in the connection member 220, and the first horizontal distance W1 may be greater than the width in the horizontal direction of the TSV. As another example, the through electrode 223 may refer to a redistribution via electrode provided in the connection member 220, and the first horizontal distance W1 may be greater than the width in the horizontal direction of the redistribution via electrode. When the first horizontal distance W1 is smaller than the width in the horizontal direction of the through electrode 223 of the connection member 220, the molding processability in the process of molding the second molding part 170 may be deteriorated.

In addition, the first part 142a of the side wall 142 of the first protective layer 140 and the side wall 151 of the molding member 150a may be spaced apart by a second horizontal distance W2. That is, if the horizontal distance W1 between the molding member 150a and the connection member 220 is too small, a molding liquid may not be filled in a process of filling the second molding part 170, and a void may be formed in the second molding part 170. Therefore, the embodiment may allow the first part 142a of the side wall 142 of the protective layer 140 and the side wall 151 of the molding member 150a to be spaced apart by a second horizontal distance W2, thereby preventing a void from being formed in the second molding part 170.

In addition, the side wall 142 of the first protective layer 140 may include an overlapping region that overlaps the molding member 150a in the vertical direction by a second horizontal distance W2, and a non-overlapping region that protrudes from the overlapping region toward the connection member 220 and does not overlap the molding member 150a in the vertical direction. At this time, the non-overlapping region of the side wall 142 of the first protective layer 140 may guide an injection position of the molding liquid in the process of filling the second molding part 170 or guide the molding liquid to easily flow into a region between the connection member 220 and the first pad part 121. In addition, the non-overlapping region of the side wall 142 of the first protective layer 140 can function as an aligning key when placing the molding member 150a, thereby enabling the molding member 150a to more stably mold the conductive bonding part 160.

The second horizontal distance W2 can be within a range of 1 μm to 10 μm. If the second horizontal distance W2 is less than 1 μm, the void may be formed in the second molding part 170, or the non-overlapping region of the side wall 142 of the first protective layer 140 corresponding to the second horizontal distance W2 may not function as an alignment key. Furthermore, if the second horizontal distance W2 exceeds 10 μm, a process time for filling the second molding part 170 may increase, resulting in a decrease in product yield or increased product manufacturing costs.

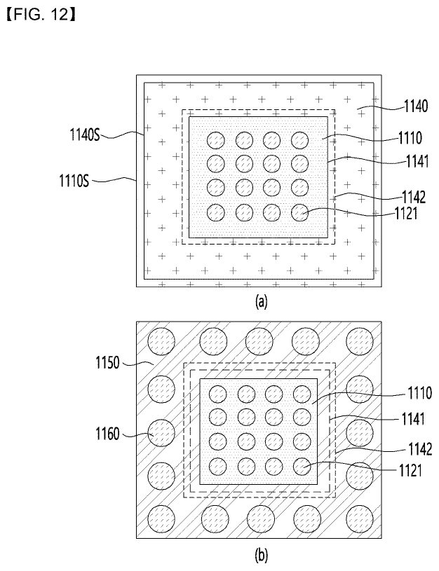

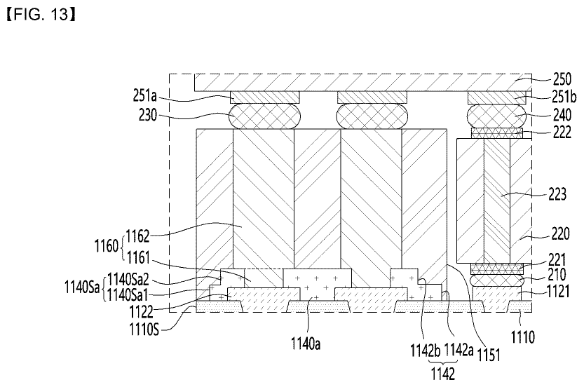

FIG. 10 is a cross-sectional view of a semiconductor package according to a fifth embodiment, FIG. 11 is an enlarged cross-sectional view of a region R1 of FIG. 10, and FIG. 12 is a plan view illustrating the first protective layer and the molding member of FIG. 10.

Referring to FIGS. 10 to 12, a semiconductor package includes a circuit board 1000, a first connecting part 210, a second connecting part 230, a third connecting part 240, a connection member 220, and semiconductor devices 250 and 255.

The circuit board 1000 includes an insulating layer 1110, a first electrode part 1120, a second electrode part 1130, a first pad part 1121, a second pad part 1122, a conductive bonding part 1160, a first protective layer 1140, a second protective layer 1145, and a molding member 1150. Here, the circuit board 1000 of the fifth embodiment may differ from the circuit board of the first embodiment in a structure of the first protective layer 1140 and a structure of the molding member 1150 according to the first protective layer 1140. Accordingly, the following description will focus on structures of the first protective layer 1140 and the molding member 1150.

An outer width of the first protective layer 1140 may be different from an outer width of the insulating layer 1110. Here, the outer width may refer to a horizontal distance between facing outer side surfaces. For example, an outer width of the first protective layer 1140 may be smaller than an outer width of the insulating layer 1110.

That is, the outer side surface 1110S of the insulating layer 1110 and the outer side surface 1140S of the first protective layer 1140 may have a step. In addition, the outer side surface 1110S of the first protective layer 1140 having the step may contact the molding member 1150. Accordingly, the contact area between the molding member 1150 and the first protective layer 1140 can be improved. Through this, the embodiment can more stably protect the conductive bonding part 1160 through the molding member 1150, thereby further improving the physical reliability and/or electrical reliability of the semiconductor package.

Furthermore, the embodiment can position the outer side surface of the first protective layer 1140 further inward than the outer side surface 1110S of the insulating layer 1110, thereby preventing warping of the semiconductor package that may occur due to a difference in the coefficient of thermal expansion of the insulating layer 1110 and the first protective layer 1140.

In addition, the molding member 1150 may be made to contact the outer side surface 1140S of the first protective layer 1140 while contacting the side wall 1142 of the opening part 1141 of the first part 1142a and the second part 1142b having a step of the first protective layer 1140. Therefore, the embodiment can more firmly fix the first protective layer 1140 through the molding member 1150 and minimize deformation of the first protective layer 1140 due to expansion and/or contraction due to the heat cycle. Therefore, the embodiment can enable the conductive bonding part 1160 to be more stably bonded.

In particular, referring to (a) of FIG. 12, the first protective layer 1140 is disposed on the insulating layer 1110. At this time, the perimeter of the outer side surface 1140S of the first protective layer 1140 does not overlap with the perimeter of the outer side surface 1110S of the insulating layer 1110 in the vertical direction. For example, the perimeter of the outer side surface 1110S of the insulating layer 1110 may be disposed further outward than the outer side surface 1140S of the first protective layer 1140.

Furthermore, referring to (b) of FIG. 12, a molding member 1150 is disposed on the insulating layer 1110 and the first protective layer 1140. The molding member 1150 may surround the outer side surface 1140S of the first protective layer 1140 having a step, and may come into contact with the side wall 1142 of the opening part 1141. Therefore, the contact area between the first protective layer 1140 and the molding member 1150 can be further improved.

FIG. 13 is a cross-sectional view illustrating a semiconductor package according to a sixth embodiment. For example, FIG. 13 is an enlarged cross-sectional view of a region R1 of FIG. 10 according to a sixth embodiment.

Referring to FIG. 13, the semiconductor package of the sixth embodiment may differ from the semiconductor package of the fifth embodiment in that the outer side surface 1140Sa of the first protective layer 1140a is inclined. Accordingly, the outer side surface 1140Sa of the first protective layer 1140a will be described below.

The outer side surface 1140Sa of the first protective layer 1140a may have a step.

For example, the outer side surface 1140Sa of the first protective layer 1140 a may include a first portion 1 1 40Sa1 that is connected to the lower surface of the first protective layer 1140a and has a step from the outer side surface 1110S of the insulating layer 1110. In addition, the outer side surface 1140Sa of the first protective layer 1140a may include a second portion 1140Sa2 that is connected to the upper surface of the first protective layer 1140a and has a step from the first portion 1140Sa1.

That is, the outer side surface 1140Sa of the first protective layer 1140a may include a first portion 1 1 40Sa1 and a second portion 1140Sa2 having a step, thereby minimizing thermal deformation caused by heat cycles due to expansion and/or contraction of the first protective layer 1140a. Furthermore, the embodiment can further increase the contact area between the molding member 1150 and the outer side surface 1140Sa of the first protective layer 1140a, thereby allowing the molding member 1150 to be more stably fixed on the first protective layer 1140a. Accordingly, the embodiment can allow the conductive bonding part 1160 to be more stably protected by the molding member 1150, thereby enabling more stable power and/or electric power supply to the semiconductor device 250 and 255. Accordingly, the semiconductor device 250 and 255 can be operated more stably.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1.-10. (canceled)

11. A circuit board comprising:
a build-up structure;
a connection member disposed on the build-up structure;
a molding member disposed on the build-up structure and surrounding a side portion of the connection member; and
a conductive bonding part penetrating the molding member,
wherein the build-up structure includes a build-up insulating layer laminated along a vertical direction and a protective layer disposed on the build-up insulating layer and including a through hole overlapping the connection member along the vertical direction,
wherein an inner wall of the through hole has a step, and
wherein at least a portion of the step is covered by the molding member.

12. The circuit board of claim 11, wherein the connection member includes a through electrode penetrating at least a portion of the connection member in the vertical direction,
wherein a thickness of the conductive bonding part in the vertical direction is greater than a thickness of the through electrode in the vertical direction, and
wherein a height of the conductive bonding part is greater than a height of the connection member.

13. The circuit board of claim 11, wherein the build-up structure further includes:
a pad part disposed on the build-up insulating layer, and
wherein the protective layer includes an opening portion that overlaps the pad part in the vertical direction.

14. The circuit board of claim 11, wherein a side wall of the protective layer having the step is provided along a circumferential direction of an outer side surface of the connection member.

15. The circuit board of claim 11, wherein a side wall of the protective layer includes a first part adjacent to a lower surface of the protective layer, and a second part provided on the first part and having a step from the first part.

16. The circuit board of claim 15, wherein at least one of the first part and the second part has a curved surface.

17. The circuit board of claim 15, wherein an opening part of the protective layer has a width in a horizontal direction in the first part greater than that in the horizontal direction in the second part.

18. The circuit board of claim 15, wherein an opening part of the protective layer has a width in a horizontal direction in the first part smaller than that in the horizontal direction in the second part.

19. The circuit board of claim 15, wherein the molding member overlaps at least a portion of an opening part of the protective layer in the vertical direction and contacts each of the first part and the second part of the side wall.

20. The circuit board of claim 15, wherein the molding member does not overlap an opening part of the protective layer in the vertical direction and contacts a portion of the second part of the side wall.

21. The circuit board of claim 11, wherein the conductive bonding part includes a first through part penetrating the protective layer; and a second through part penetrating the molding member.

22. The circuit board of claim 21, wherein a width of the first through part in a horizontal direction is different from a width of the second through part in the horizontal direction.

23. The circuit board of claim 11, wherein an outer side surface of the protective layer has a step from an outer side surface of the build-up insulating layer.

24. The circuit board of claim 23, wherein the molding member is provided to cover the outer side surface of the protective layer.

25. The circuit board of claim 24, wherein the outer side surface of the protective layer includes a first portion having a step from the outer side surface of the build-up insulating layer, and a second portion having a step from the outer side surface of the build-up insulating layer and the first portion, and
wherein the molding member contacts the first portion and the second portion.

26. The circuit board of claim 11, further comprising:
a plurality of semiconductor devices disposed on the conductive bonding part.

27. A circuit board comprising:
a build-up insulating layer;
a protective layer disposed on the build-up insulating layer,
a molding member disposed on the protective layer; and
a conductive bonding part disposed on the build-up insulating layer and penetrating the protective layer and the molding member,
wherein an outer surface of the protective layer has a step from an outer surface of the build-up insulating layer, and
wherein the molding member covers the outer surface of the protective layer.

28. The circuit board of claim 27, wherein the outer surface of the protective layer includes a first portion having a step from the outer surface of the build-up insulating layer, and a second portion having a step from the outer surface of the build-up insulating layer and the first portion, and
wherein the molding member contacts the first portion and the second portion.

29. The circuit board of claim 27, further comprising:
a connection member disposed on the build-up insulating layer,
wherein the protective layer includes a through hole overlapping the connection member in a vertical direction,
wherein a side wall of the through hole of the protective layer having a step, and
wherein the molding member contacting the step of the side wall of the through hole of the protective layer.

30. The circuit board of claim 29, further comprising:
a plurality of semiconductor devices disposed on the conductive bonding part and the connection member.
